(19) United States
(12) Patent Application Publication
(10) Pub. No.: US 2010/0097854 A1
(43) Pub. Date: Apr. 22, 2010

(54) FLASH MEMORY AND FLASH MEMORY ARRAY

(75) Inventors: Jen-Jui Huang, Taoyuan County (TW); Hung-Ming Tsai, Kaohsiung City (TW); Kuo-Chung Chen, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 12/352,588

(22) Filed: Jan. 12, 2009

(30) Foreign Application Priority Data
Oct. 21, 2008 (TW) 97140341

(51) Int. Cl. G11C 16/04; H01L 29/788; H01L 27/115

(52) U.S. Cl. 365/185.01; 257/316; 257/E29.3; 257/E27.103

(57) ABSTRACT

A flash memory including a substrate having a recess, a buried bit line, a word line, a single side insulating layer, a floating gate, a tunneling dielectric layer, a control gate, and an inter-gate dielectric layer is provided. The buried bit line extends below the recess of the substrate along a first direction. The word line is on the substrate, and extends above the recess along a second direction. The single side insulating layer is on a first sidewall of the recess. The floating gate is on a second sidewall of the recess to be opposite to the single side insulating layer. The tunneling dielectric layer is sandwiched by the floating gate and the substrate to contact the buried bit line. The control gate fills the recess and contacts the word line. The inter-gate dielectric layer is sandwiched by the control gate and the floating gate.

### CROSS-REFERENCE TO RELATED APPLICATION

This application claims the priority benefit of Taiwan application serial no. 97140341, filed on Oct. 21, 2008. The entirety of the above-mentioned patent application is hereby incorporated by reference herein and made a part of specification.

### BACKGROUND OF THE INVENTION

1. Field of the Invention

The present invention generally relates to a memory, more particularly to a flash memory and a flash memory array.

2. Description of Related Art

A flash memory can be used to perform data saving, reading, and erasing operations repeatedly for many times, and the data saved in the flash memory will not disappear after the power is turned off. Therefore, the flash memory has become a non-volatile memory device widely used in personal computers and various electronic devices.

In a conventional flash memory, a floating gate and a control gate are fabricated with doped polysilicon. Moreover, the control gate is directly disposed on the floating gate, an inter-gate dielectric layer is sandwiched by the floating gate and the control gate, and the floating gate and a substrate are spaced by a tunneling oxide layer. Thus, a stacked-gate flash memory is formed.

However, as the integrated circuit has been miniaturized at a higher integration degree, the size of the flash memory needs to be reduced. Therefore, a memory device with flash memories configured in trench has been developed in recent years, for example, Republic Of China Patent Publication No. TW283912(B), filed on Oct. 21, 2002. However, the distance between trenches will be reduced as the size of the device becomes smaller, so that electrical interference often occurs between flash memories.

### SUMMARY OF THE INVENTION

Accordingly, the present invention is directed to a flash memory array, which is suitable for preventing electrical interference between flash memories.

As embodied and broadly described herein, the present invention provides a flash memory, which includes a substrate, a buried bit line, a word line, a single side insulating layer, a floating gate, a tunneling dielectric layer, a control gate, and an inter-gate dielectric layer. The substrate has a recess. The buried bit line extends below the recess of the substrate along a first direction. The word line is disposed on the substrate, and extends above the recess along a second direction, wherein the first direction and the second direction are distinct from one another. The single side insulating layer is disposed on a first sidewall of the recess. In addition, the floating gate is disposed on a second sidewall of the recess to be opposite to the single side insulating layer. The tunneling dielectric layer is sandwiched by the floating gate and the substrate to contact the buried bit line. The control gate fills the recess, and contacts the word line. The inter-gate dielectric layer is sandwiched by the control gate and the floating gate.

The present invention further provides a flash memory array, which includes a substrate, a plurality of buried bit lines, a plurality of word lines, a plurality of single side insulating layers, a plurality of floating gates, a plurality of tunneling dielectric layers, a plurality of control gates, a plurality of inter-gate dielectric layers, and a plurality of contacts. The substrate has a plurality of recesses. The buried bit lines extend below the recesses of the substrate along a first direction. The word lines are disposed on the substrate, and extend above the recesses along a second direction. Moreover, the single side insulating layers extend on a first sidewall of each of the recesses along the second direction respectively. The floating gates are disposed on a second sidewall opposite to the first sidewall of each of the recesses respectively. The tunneling dielectric layers are sandwiched by a surface of each of the floating gates and a surface of each of the recesses, and contact the buried bit lines in the first direction. The control gates fill each of the recesses respectively, and contact the word lines in the second direction. The inter-gate dielectric layers are sandwiched by the control gates and the floating gates. In addition, the contacts are connected to the substrate adjacent to each of the recesses.

The present invention uses embedded gate structures, and vertically disposes the gate structures of the entire flash memories into the substrate. Therefore, the size of the obtained element is extremely small, which meets the development trend of miniaturizing the elements. In addition, the present invention may include the single side insulating layers, which can prevent the electrical interference between the flash memories in the memory array.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic three-dimensional view of a flash memory according to a first embodiment of the present invention.

FIGS. 2A, 3A, 8A, 9A, 10A, 11A, 12A, 13A, 14A, 15A, and 16A are top views of a process for manufacturing a flash memory array according to a second embodiment of the present invention.

FIGS. 2B, 3B, 8B, 9B, 10B, 11B, 12B, 13B, 14B, 15B, and 16B are cross-sectional views of FIGS. 2A, 3A, 8A, 9A, 10A, 11A, 12A, 13A, 14A, 15A, and 16A respectively, taken along a cross-section line B-B.

FIGS. 4, 5, 6, and 7 are schematic cross-sectional views of subsequent manufacturing process after the process shown in FIG. 2B.

FIGS. 8C, 9C, 10C, 11C, 13C, 14C, 15C, and 16C are cross-sectional views of FIGS. 8A, 9A, 10A, 11A, 13A, 14A, 15A, and 16A respectively, taken along a cross-section C-C.

FIGS. 8D, 9D, 10D, 14D, 15D, and 16D are cross-sectional views of FIGS. 8A, 9A, 10A, 14A, 15A, and 16A respectively, taken along a cross-section D-D.

FIGS. 14E and 15E are cross-sectional views of FIGS. 14A and 15A respectively, taken along a cross-section E-E.

FIG. 17 is a schematic three-dimensional view of a flash memory array according to a third embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

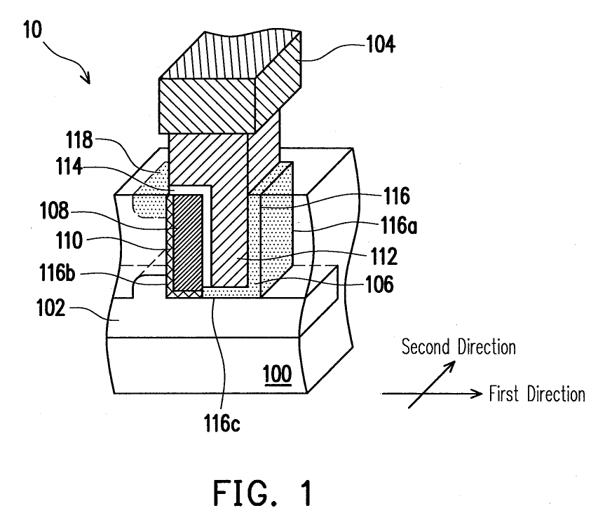

FIG. 1 is a schematic three-dimensional view of a flash memory according to a first embodiment of the present invention.

Referring to FIG. 1, a flash memory 10 according to the first embodiment includes a substrate 100, a buried bit line 102, a word line 104, a single side insulating layer 106, a floating gate 108, a tunneling dielectric layer 110, a control gate 112, and an inter-gate dielectric layer 114. The substrate 100 has a recess 116. The buried bit line 102 extends below the recess 116 of the substrate 100 along a first direction. The word line 104 is disposed on the substrate 100, and extends above the recess 116 along a second direction that is distinct from the first direction. The single side insulating layer 106 is disposed on a first sidewall 116a of the recess 116. The single side insulating layer 106 is made of, for example, an oxide or another appropriate insulating material. In addition, in the first embodiment, beside being disposed on the first sidewall 116a of the recess 116, the single side insulating layer 106 may be disposed on a part of a bottom wall 116c of the recess 116. The floating gate 108 is disposed on a second sidewall 116b of the recess 116 to be opposite to the single side insulating layer 106, and the floating gate 108 does not cover the entire bottom wall 116c of the recess 116, but is disposed on a part of the bottom wall 116c of the recess. The tunneling dielectric layer 110 is sandwiched by a surface of the floating gate 108 and a surface of the substrate 100 to contact the buried bit line 102. The tunneling dielectric layer 110 is made of, for example, an oxide. The control gate 112 fills the remaining part of the recess 116, and contacts the single side insulating layer 106 on the bottom wall 116c of the recess 116. The control gate 112 further contacts the word line 104, so as to be configured into an L-shaped structure. In FIG. 1, besides being disposed in the recess 116, the control gate 112 may further protrude out of the recess 116 and cover the floating gate 108. Alternatively, the control gate 112 may also cover the single side insulating layer 106. The inter-gate dielectric layer 114 is sandwiched by the control gate 112 and the floating gate 108. The inter-gate dielectric layer is made of, for example, ONO (oxide-nitride-oxide), a material with high dielectric constant, or another appropriate dielectric material. Furthermore, the flash memory 10 of this embodiment may further include a doped region 118 disposed in the substrate 100 adjacent to the tunneling dielectric layer 110.

The elements in the first embodiment may be arranged in an array. Then, an exemplary process is described below for demonstration. However, the manufacturing method of the elements of the present invention is not limited hereby.

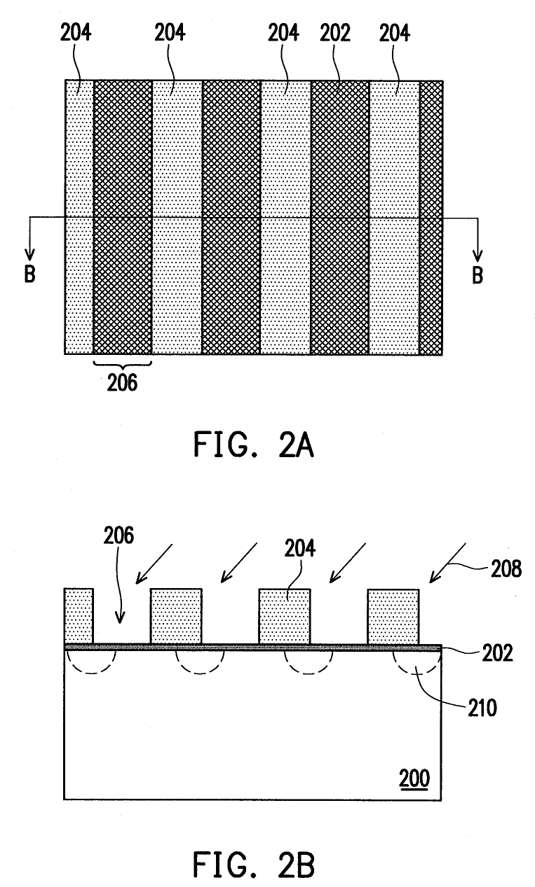

FIGS. 2A-15D are schematic views of a process for manufacturing a flash memory array according to a second embodiment of the present invention.

Referring to FIGS. 2A and 2B, a pad oxide layer 202 and a silicon nitride layer 204 are formed on a substrate 200 first, and trenches 206 are formed in the silicon nitride layer 204. Then, a tilt implantation process 208 is performed to form a doped region 210 in the substrate 200.

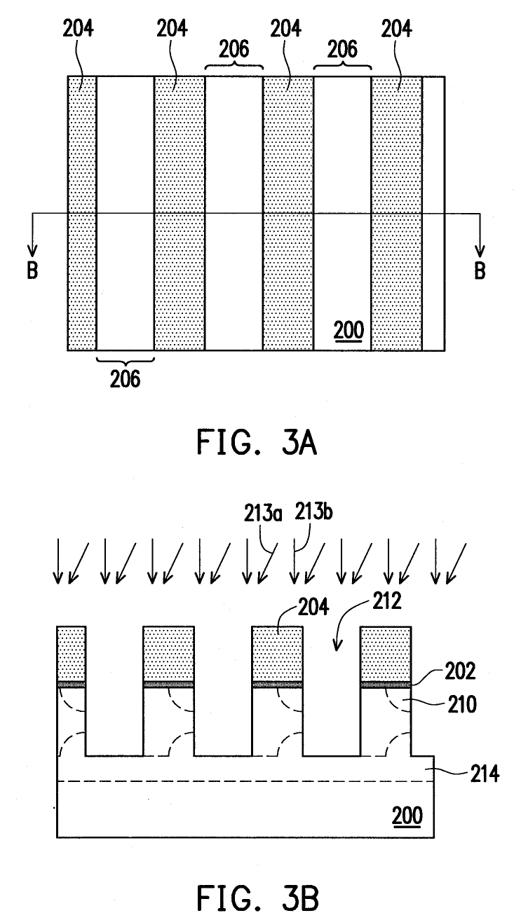

Then, referring to FIGS. 3A and 3B, the patterned silicon nitride layer 204 is used as a mask to etch the pad oxide layer 202 and the substrate 200, so as to form a plurality of first trenches 212. Next, a tilt implantation process 213a and a vertical implantation process 213b are performed to form another doped region 214 in the substrate 200 below the first trenches 212.

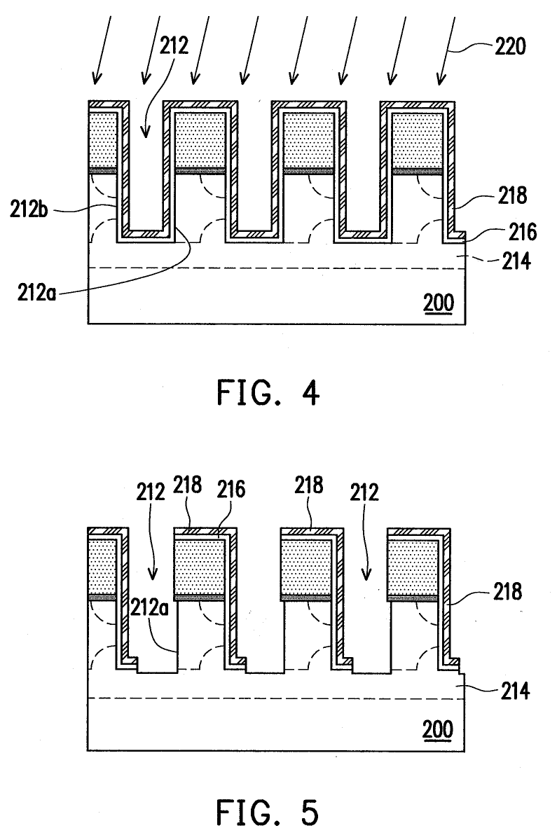

Then, in order to enable the present invention to be applicable to shield small-sized trenches, an isolating structure will be formed on a sidewall 212a of each of the first trenches 212. Referring to FIG. 4, a silicon nitride liner 216 and a polysilicon liner 218 are sequentially formed on the entire surface of the substrate 200 and the first trenches 212, and then a single side implantation process 220 is performed, such that the sidewall 212a of each of the first trenches 212 has the polysilicon liner 218 that is not implanted, and the other sidewall 212b thereof has the modified polysilicon liner 218.

Next, referring to FIG. 5, the polysilicon liner 218 that is not implanted on the sidewall 212a of each of the first trenches 212 is removed, and meanwhile the silicon nitride liner 216 at the same position is also removed. After that, a part of the substrate 200 is slightly removed through a wet etching process.

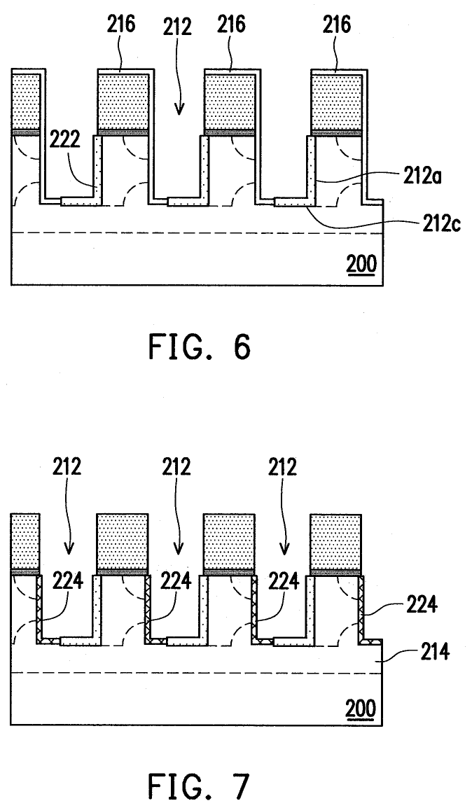

Then, referring to FIG. 6, all of the modified polysilicon liner 218 is removed, and a local oxidation of silicon (LOCOS) process is performed on the exposed substrate 200 by using the remaining silicon nitride liner 216 as a mask, so as to form a single side insulating layer 222 on the sidewall 212a of each of the first trenches 212. In FIG. 6, the single side insulating layer 222 is further disposed on a part of the bottom wall 212c of each of the first trenches 212. According to the process shown in FIG. 5, it is known that, the single side insulating layer 222 may be made of an oxide. However, in the present invention, another deposition process may be used to form other appropriate insulating materials on the sidewall 212a of each of the first trenches 212, so as to serve as the single side insulating layer 222.

Then, referring to FIG. 7, the silicon nitride liner 216 is removed, and a tunneling dielectric layer 224 is formed on the surface of the substrate 200 exposed in each of the first trenches 212. The tunneling dielectric layer 224 is made of an oxide.

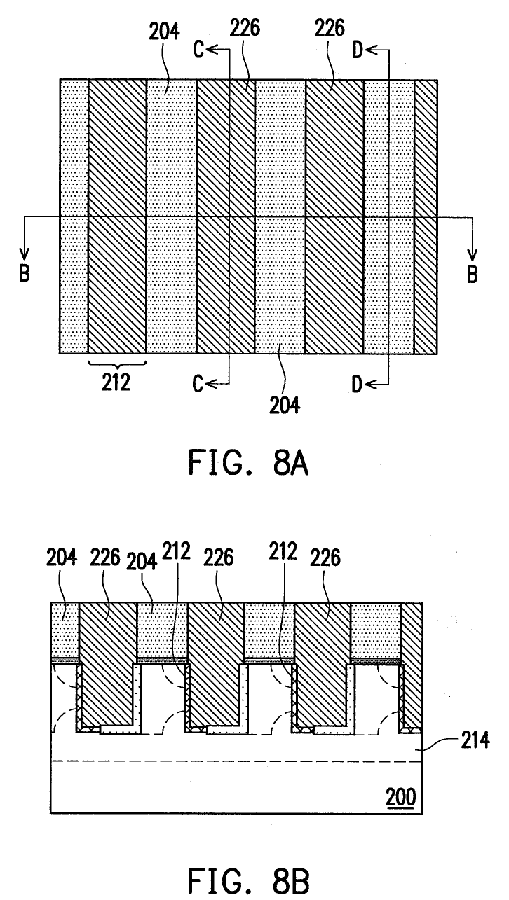

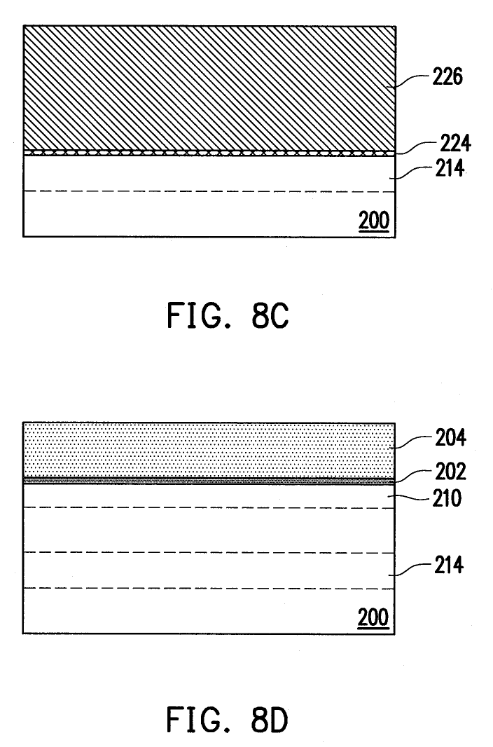

Next, referring to FIGS. 8A-8D, a conductive material 226 is filled in each of the first trenches 212, and a planarization process is performed to expose the surface of the silicon nitride layer 204.

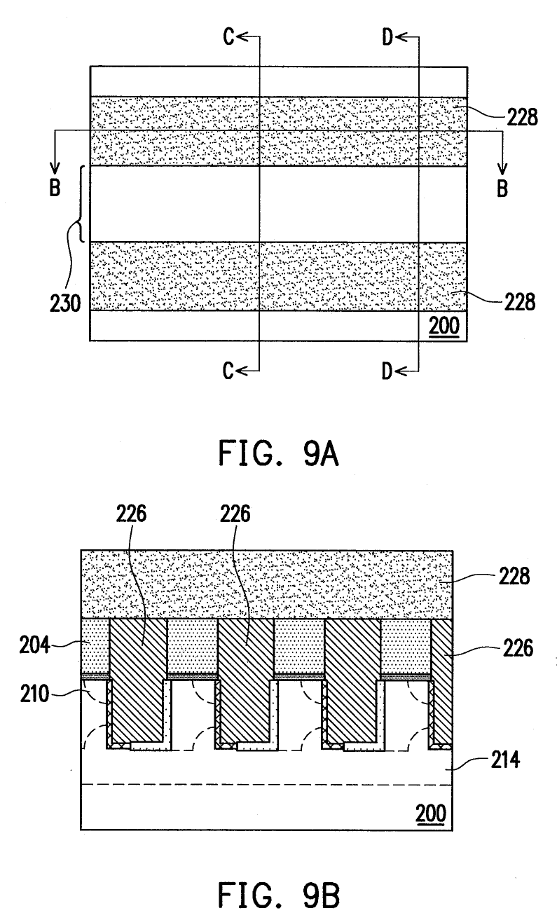

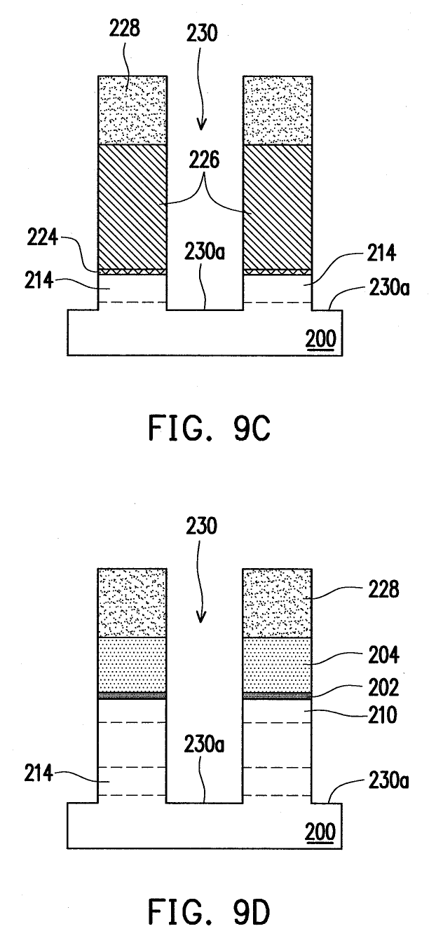

Then, referring to FIGS. 9A-9D, an active area is defined in the substrate, for example, a lithography and etching process is performed to form a patterned mask 228 on the substrate. The patterned mask 228 is made of, for example, an oxide, and the patterned mask 228, for example, extends along a direction perpendicular to the extending direction of the first trenches 212 (shown in FIG. 8A). Then, the patterned mask 228 is used as an etching mask to etch the substrate 200 until a plurality of second trenches 230 is formed. At this time, a bottom wall 230a of the second trenches 230 is lower than the doped region 214. Therefore, the doped region 210 and the conductive material 226 will form a discontinuous structure. Similarly, the doped region 214 below the first trenches 212 will form the buried bit line along the same extending direction as the patterned mask 228.

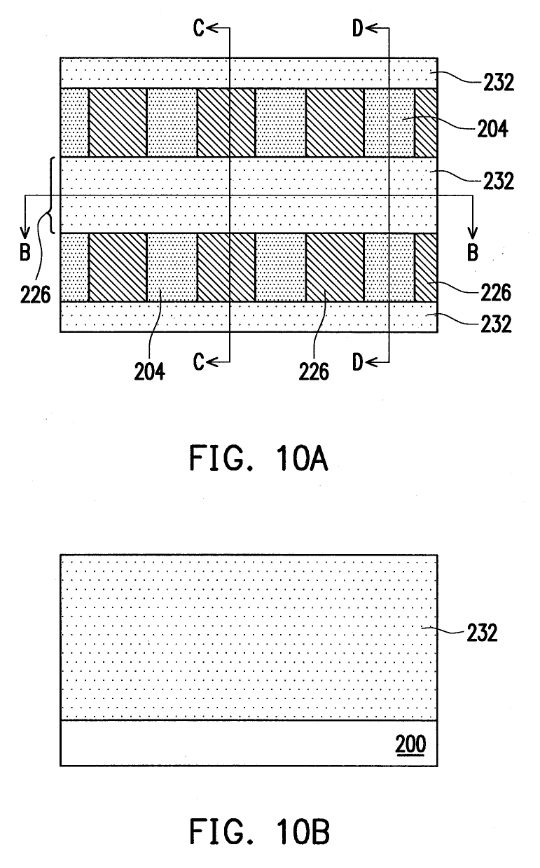

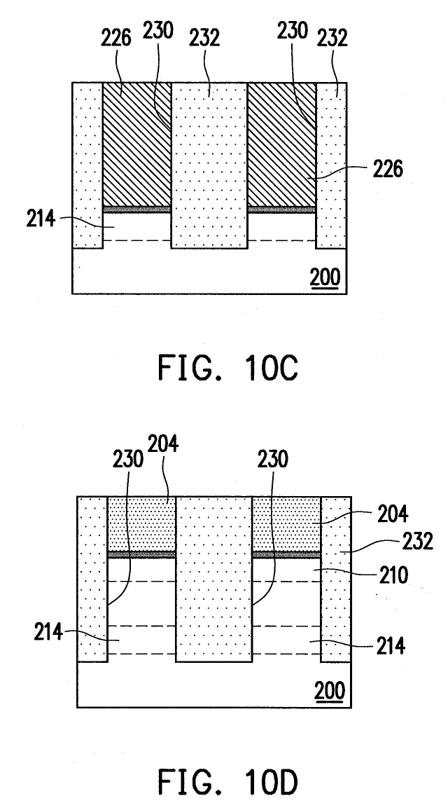

Next, referring to FIGS. 10A-10D, the patterned mask 228 is removed, and an insulating material 232 (for example, an oxide) is filled in the second trenches 230. Meanwhile, a planarization process is performed to expose the surface of the silicon nitride layer 204. At this time, the silicon nitride layer 204, the single side insulating layer 222, the tunneling dielectric layer 224, and the insulating material 232 together form a structure similar to a recess, and the conductive material 226 is disposed in the structure.

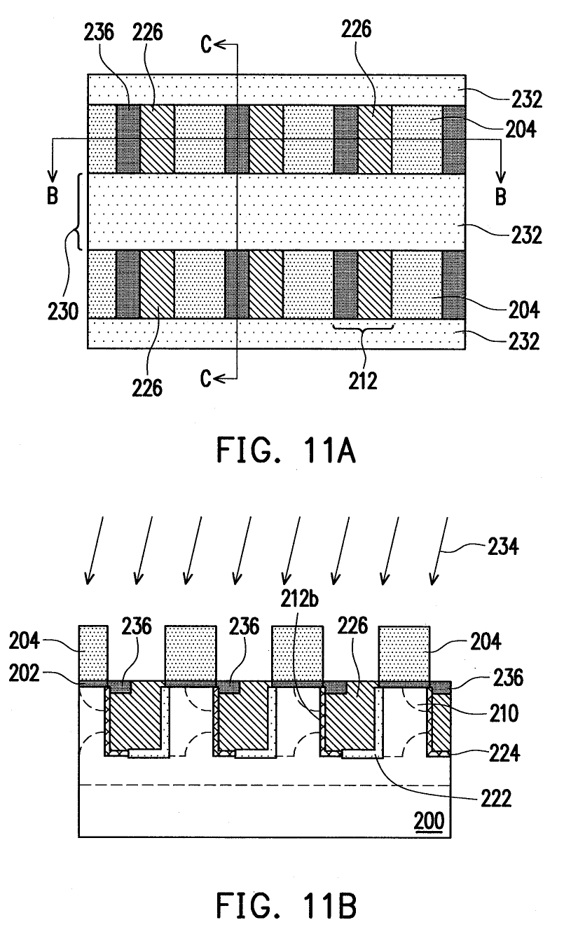

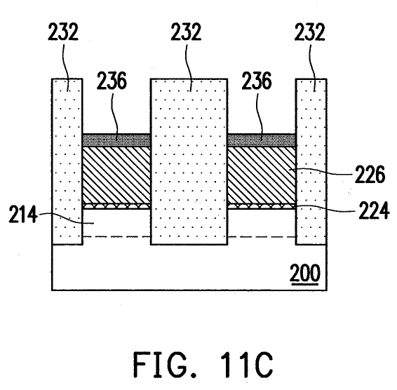

Then, referring to FIGS. 11A-11C, the conductive material 226 is etched back, such that the top surface of the conductive material 226 is close to the position of the pad oxide layer 202. After that, another single side implantation process 234 is performed, such that a part of the top surface of the conductive material 226 on the sidewall 212b of each of the first trenches 212 is formed into a modified layer 236.

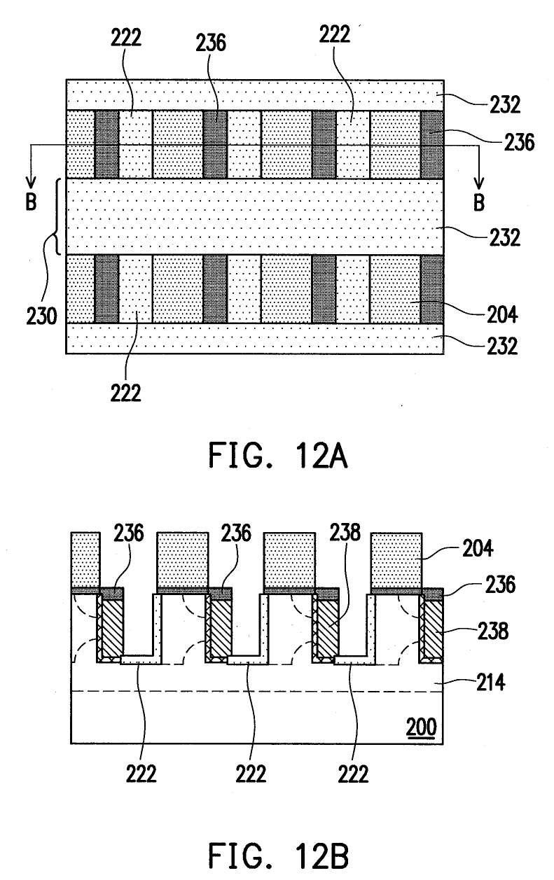

Then, referring to FIGS. 12A and 12B, the conductive material 226 not shielded by the modified layer 236 is etched off by using the modified layer 236 as a mask, so as to form a floating gate 238.

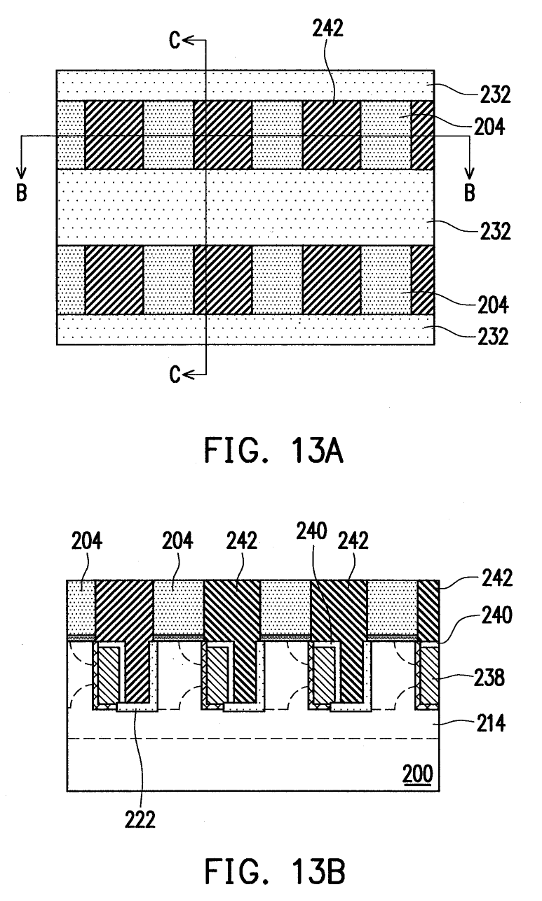

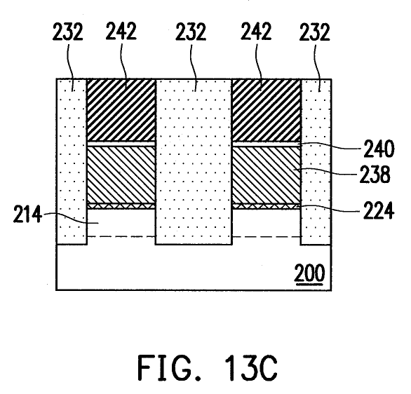

Next, referring to FIGS. 13A-13C, the modified layer 236 may be retained or removed. In this embodiment, the modified layer 236 is removed. Then, a deposition process is performed to form an inter-gate dielectric layer 240 on the surface of the floating gate 238. The inter-gate dielectric layer 240 is made of, for example, ONO, a material with high dielectric constant, or another appropriate dielectric material. Next, a control gate 242 is formed in the recess formed by the silicon nitride layer 204, the single side insulating layer 222, the insulating material 232, and the inter-gate dielectric layer 240. Meanwhile, a planarization process may be performed to expose the surface of the silicon nitride layer 204. At this time, the control gates 242 are formed into a discontinuous structure.

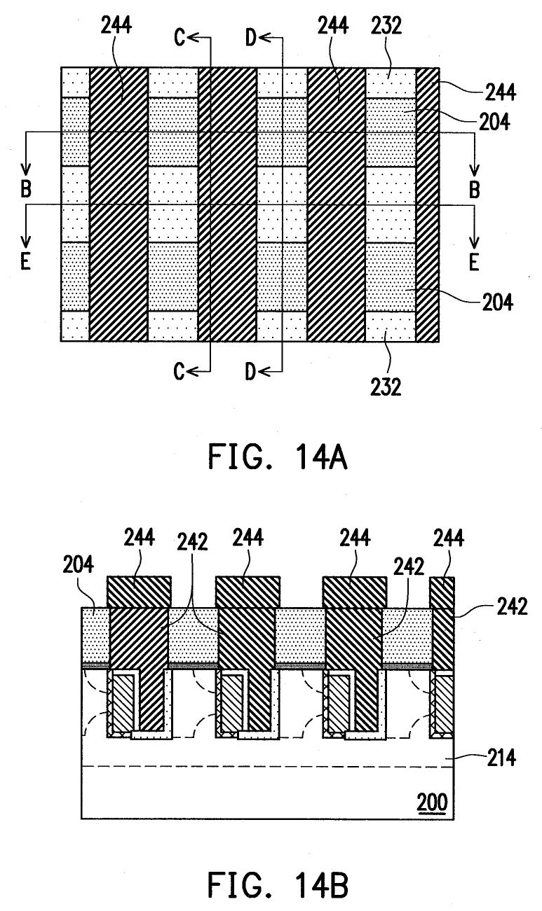

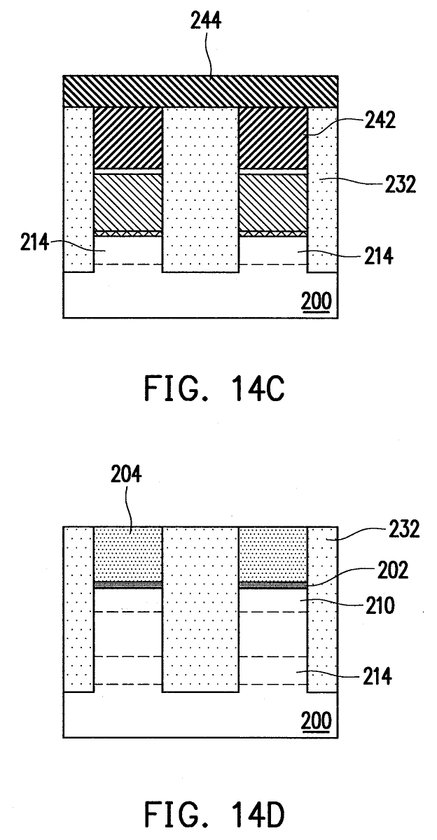

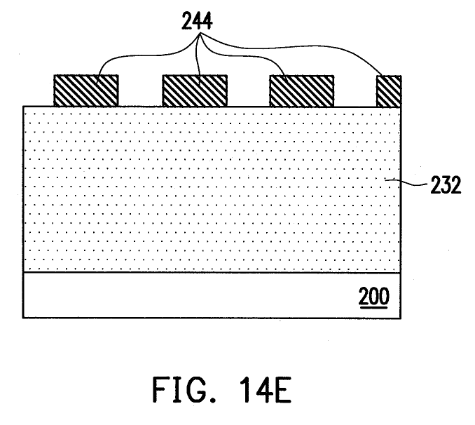

Next, referring to FIGS. 14A-14E, word lines 244 are formed on the substrate 200. The extending direction of the word lines 244 is perpendicular to the doped region 214 (that is, the buried bit line), and the word lines 244 are connected to the control gates 242 in the same extending direction.

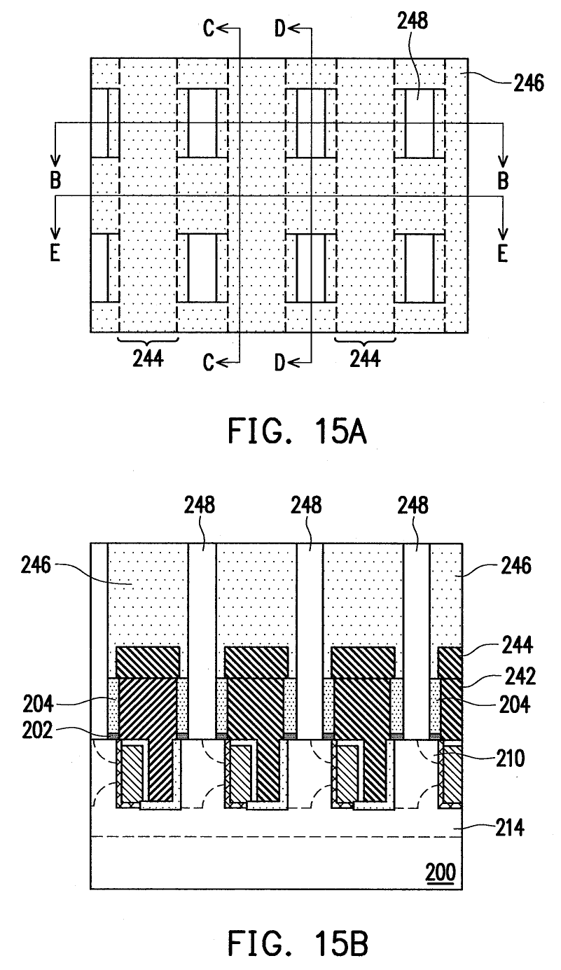

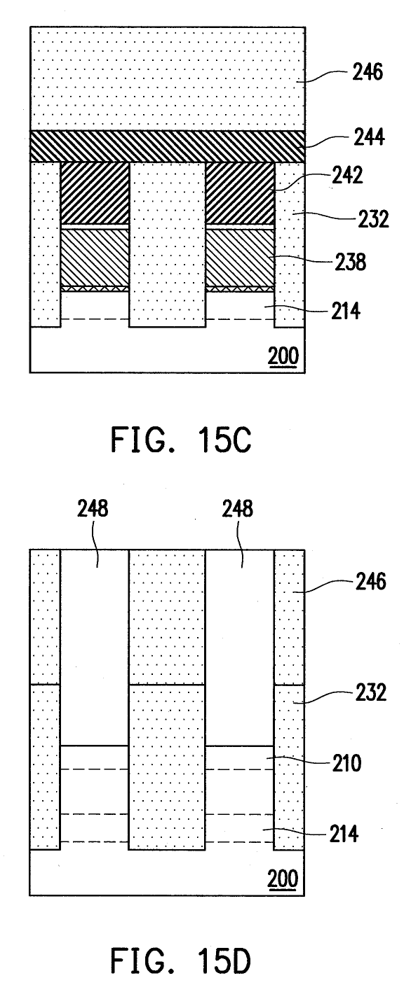

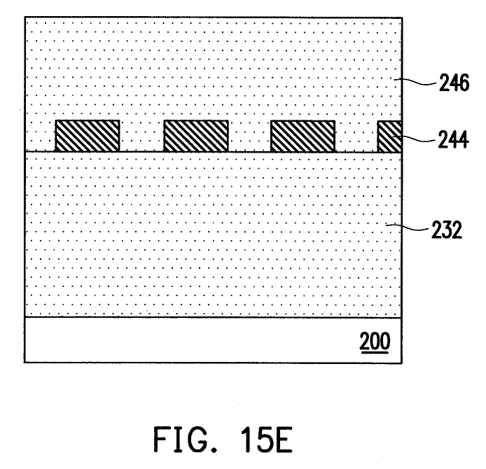

Then, referring to FIGS. 15A-15E, an inter-layer dielectric layer 246 is formed on the surface of the substrate 200, and a plurality of contacts 248 electrically connected to the doped region 210 is formed between the word lines 244 in the inter-layer dielectric layer 246, the silicon nitride layer 204, and the pad oxide layer 202.

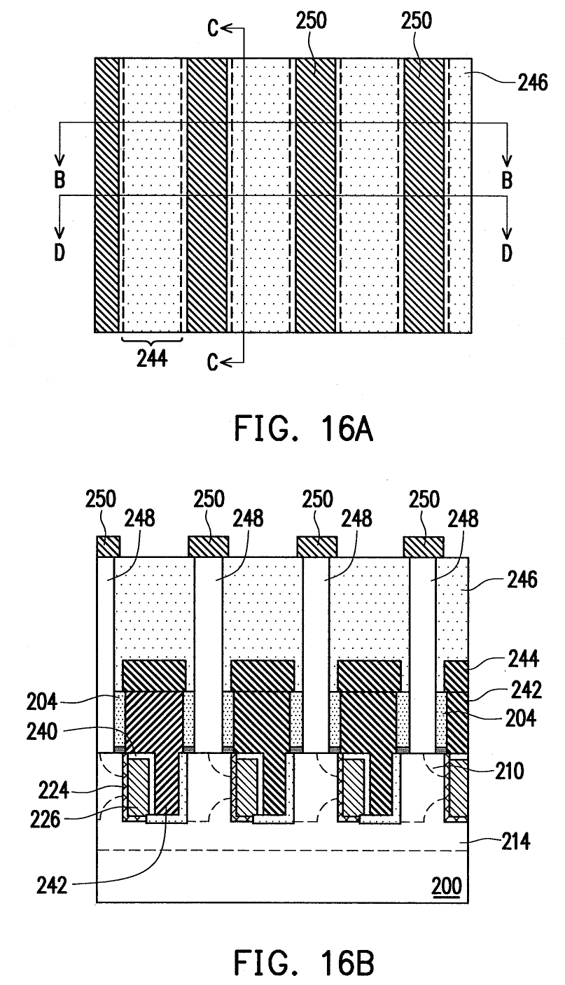

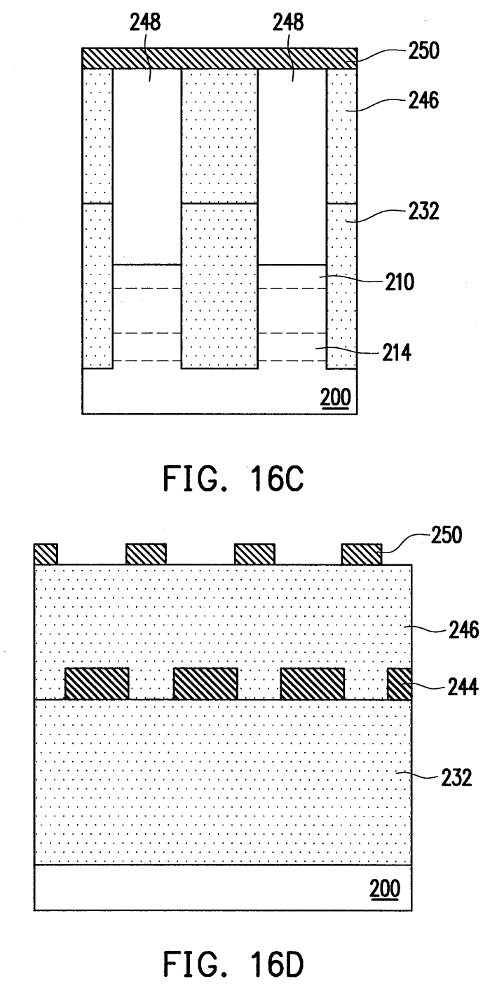

Finally, referring to FIGS. 16A-16D, common source lines 250 parallel to the extending direction of the word lines 244 may be optionally formed on the inter-layer dielectric layer 246.

Furthermore, FIGS. 16A-16D may be modified as follows: the common source lines 250 are directly defined during the process of forming the contacts 248.

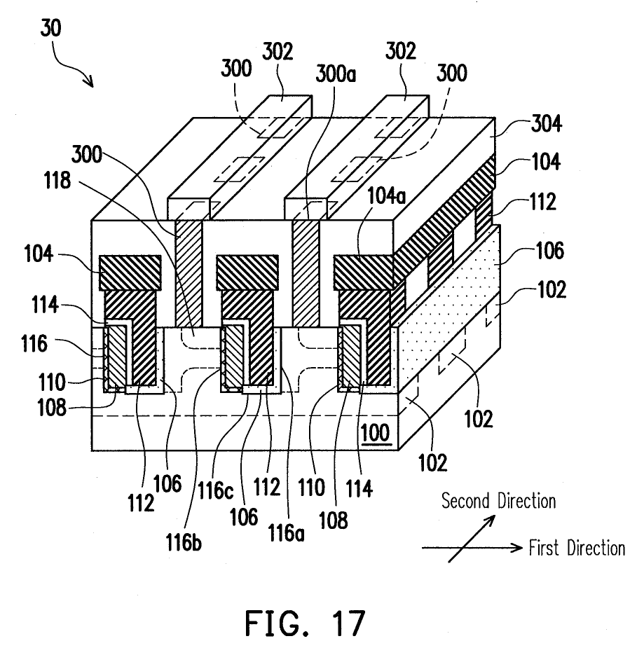

FIG. 17 is a schematic three-dimensional view of a flash memory array according to a third embodiment of the present invention, in which the same reference numerals indicate the same components as in the first embodiment.

Referring to FIG. 17, a flash memory array 30 according to the third embodiment includes a substrate 100, a plurality of buried bit lines 102, a plurality of word lines 104, a plurality of single side insulating layers 106, a plurality of floating gates 108, a plurality of tunneling dielectric layers 110, a plurality of control gates 112, a plurality of inter-gate dielectric layers 114, and a plurality of contacts 300. The substrate 100 has a plurality of recesses 116. The buried bit lines 102 extend below the recesses 116 of the substrate 100 along a first direction. The word lines 104 are disposed on the substrate 100, and extend above the recesses 116 along a second direction. Moreover, the single side insulating layers 106 extend on a first sidewall 116a of each of the recesses 116 along the second direction, and the single side insulating layers 106 are further disposed on a part of a bottom wall 116c of each of the recesses 116. The single side insulating layers 106 are made of, for example, an oxide or another appropriate insulating material. The floating gates 108 are respectively disposed on a second sidewall 116b opposite to the first sidewall 116a of each of the recesses 116. Each of the tunneling dielectric layers 110 is sandwiched by a surface of each of the floating gates 108 and a surface of each of the recesses 116. The tunneling dielectric layers 110 contact the buried bit lines 102 in the first direction. The tunneling dielectric layers 110 are made of, for example, an oxide.

Referring to FIG. 17 again, the control gates 112 fill up each of the recesses 116, and contact the word lines 104 in the second direction. Therefore, the control gates 112 in the third embodiment may be regarded as a discontinuous structure. In addition, the control gates 112 may also protrude out of the recesses 116, as shown in FIG. 17. The inter-gate dielectric layers 114 are sandwiched by the control gates 112 and the floating gates 108. The inter-gate dielectric layers 114 are made of, for example, ONO, a material with high dielectric constant, or another appropriate dielectric material. In addition, the contacts 300 are respectively connected to the substrate 100 adjacent to each of the recesses 116. In order to ensure that the subsequent interconnects do not contact the word lines 104, the top surfaces 300a of the contacts 300 may be higher than top surfaces 104a of the word lines 104. The flash memory array 30 may further include a plurality of doped regions 118, which are respectively disposed in the substrate 100 adjacent to each of the tunneling dielectric layers 110, such that the contacts 300 are connected to each of the doped regions 118. Moreover, the flash memory array 30 may further include a plurality of common source lines 302, which extend above the substrate 100 along the second direction and respectively contact the contacts 300 in the second direction. Furthermore, an inter-layer dielectric layer 304 may be sandwiched by the contacts 300 and the word lines 104 to serve as an isolating structure.

To sum up, the structure of the present invention can be disposed in the substrate in a completely vertical manner, which thus meets the current miniaturization trend of elements, and can effectively prevent the electrical interference between flash memory elements.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A flash memory, comprising:
a substrate, comprising a recess;
a buried bit line, extending below the recess of the substrate along a first direction;
a word line, disposed on the substrate, and extending above the recess along a second direction, wherein the first direction and the second direction are distinct from one another;
a single side insulating layer, disposed on a first sidewall of the recess;
a floating gate, disposed on a second sidewall of the recess to be opposite to the single side insulating layer;
a tunneling dielectric layer, sandwiched by the floating gate and the substrate to contact the buried bit line;
a control gate, disposed in the recess and in contact with the word line; and
an inter-gate dielectric layer, sandwiched by the control gate and the floating gate.

2. The flash memory according to claim 1, wherein the single side insulating layer is further disposed on a part of a bottom wall of the recess.

3. The flash memory according to claim 2, wherein the floating gate is further disposed on a part of a bottom wall of the recess.

4. The flash memory according to claim 3, wherein the control gate protrudes out of the recess.

5. The flash memory according to claim 4, wherein the control gate further covers the floating gate and the single side insulating layer.

6. The flash memory according to claim 4, wherein the control gate is configured into an L-shaped structure.

7. The flash memory according to claim 2, wherein the floating gate is further disposed on a part of the bottom wall of the recess.

8. The flash memory according to claim 7, wherein the control gate protrudes out of the recess.

9. The flash memory according to claim 8, wherein the control gate further covers the floating gate and the single side insulating layer.

10. The flash memory according to claim 8, wherein the control gate is configured into an L-shaped structure.

11. The flash memory according to claim 1, further comprising a doped region disposed in the substrate adjacent to the tunneling dielectric layer.

12. A flash memory array, comprising:
a substrate, comprising a plurality of recesses;
a plurality of buried bit lines, extending below the recesses of the substrate along a first direction;
a plurality of word lines, disposed on the substrate, and extending above the recesses along a second direction;
a plurality of single side insulating layers, extending on a first sidewall of each of the recesses along the second direction respectively;
a plurality of floating gates, disposed on a second sidewall opposite to the first sidewall of each of the recesses respectively;
a plurality of tunneling dielectric layers, sandwiched by a surface of each of the floating gates and a surface of each of the recesses, wherein the tunneling dielectric layers contact the buried bit lines in the first direction;
a plurality of control gates, disposed in each of the recesses and in contact with the word lines in the second direction respectively;
a plurality of inter-gate dielectric layers, sandwiched by the control gates and the floating gates; and
a plurality of contacts, disposed between the plurality of word lines respectively, and connected to the substrate adjacent to each of the recesses.

13. The flash memory array according to claim 12, wherein the single side insulating layers are further disposed on a part of a bottom wall of each of the recesses respectively.

14. The flash memory array according to claim 12, wherein the control gates protrude out of the recesses.

15. The flash memory array according to claim 12, further comprising a plurality of doped regions disposed in the substrate adjacent to each of the tunneling dielectric layers.

16. The flash memory array according to claim 15, wherein the contacts are connected to each of the doped regions respectively.

17. The flash memory array according to claim 16, further comprising a plurality of common source lines extending on the substrate along the second direction, and contacting the contacts in the second direction.

18. The flash memory array according to claim 17, wherein top surfaces of the contacts are higher than top surfaces of the word lines.

19. The flash memory array according to claim 12, further including an inter-layer dielectric layer disposed between the contacts and the word lines.
